(19) United States
(12) Patent Application Publication
(10) Pub. No.: US 2007/0033151 A1
(43) Pub. Date: Feb. 8, 2007

(54) Systems, Methods, and Apparatuses for Reporting Transient Conditions in an Unattended Meter

(75) Inventor: Robert E. Lee Jr., Dover, NH (US)

Correspondence Address: SUTHERLAND ASBILL & BRENNAN LLP, 999 PEACHTREE STREET, N.E., ATLANTA, GA, 30309, US

(73) Assignee: GENERAL ELECTRIC COMPANY, Schenectady, NY (US)

(21) Appl. No.: 11/161,411

(22) Filed: Aug. 2, 2005

(51) Int. Cl. G01R 21/133

(52) U.S. Cl. 705/412

(57) ABSTRACT

Systems, methods, and apparatuses are disclosed in which a meter may detect and record transient conditions for a billing period. The transient conditions may be stored in a queue. The meter may then obtain transient conditions that occur during a billing period. One or more transient conditions may be displayed by the meter. The meter may also communicate the transient conditions to a communications system.

### BACKGROUND OF THE INVENTION

1. Field of the Invention

Aspects of the present invention relate generally to meters, and more particularly, to systems, methods, and apparatuses for storing and reporting transient conditions detected by the meters.

2. Description of the Related Art

Current solid-state electricity meters may be used to monitor for transient conditions. These transient conditions may occur for a period of time, but the condition may typically resolve itself on its own. Utility companies are interested in these transient conditions in order to investigate or resolve frequently-occurring transient conditions.

Many electricity meters currently operate under the assumption that the utility company will interact with the meters at the end of each billing period. In many of these meters, the transient conditions are latched. Thus, when a transient condition is detected by the electricity meter, it is latched and remains in the meter until the latched condition is specifically acknowledged and cleared by the utility company. This acknowledgement may come from a meter reader visiting the meter with the latched condition and pressing a reset button. Likewise, this acknowledgement may come from a meter reader interacting with the meter through an optical port. Any conditions that are captured during the billing period may be seen when reading the meter and cleared during the interaction.

During normal operation of the electricity meters, however, utility companies preferably should not need to dispatch meter readers to clear a condition or reprogram a schedule. Similarly, a two-way automatic meter reading (AMR) system should not need to interact with a meter to clear a condition. Such an interaction between the meter readers and the electricity meters costs utility companies substantial resources including time and money. Accordingly, there is a need in the industry for electricity meters that can minimize these interactions by automatically recording and reporting transient conditions with requiring the utility company to visit the meter or communicate with the meter in order to acknowledge or clear the conditions.

### BRIEF DESCRIPTION OF THE INVENTION

According to embodiments of the present invention, electricity meters may monitor for and detect transient conditions. The detected transient conditions may be stored in a memory of the meters. The memory of the meters may implement a queue for storing the detected transient conditions. The meter may also have a display for rendering indications of the transient conditions. The meter may also have a communications module for transmitting indications of the transient conditions to a non-fixed (e.g., a drive-by vehicle) automatic meter reading (AMR) system.

According to an embodiment of the invention, there is disclosed a method for recording transient conditions in a meter. The method includes providing a queue having a plurality of entries spanning a number of time periods, storing one or more transient conditions for a current time period in a first entry in the queue, at an end of the current time period, initializing a second entry in the queue for storing transient conditions for another time period subsequent to the current time period, where the second entry overwrites an oldest entry in the queue, and presenting one or more of the identified stored transient conditions.

According to an aspect of the invention, presenting the identified stored transient conditions includes displaying the identified stored transient conditions on a display associated with the meter. According to another aspect of the invention, presenting the identified stored transient conditions includes transmitting the identified stored transient conditions to an automatic meter reading system. According to yet another aspect of the invention, providing a queue includes providing a queue having a plurality of entries based at least in part on a number of business days in a billing period.

In addition, according to an aspect of the invention, storing one or more transient conditions includes storing one or more transient conditions associated with power quality. According to another aspect of the invention, storing one or more transient conditions includes storing one or more transient conditions associated with meter hardware errors. According to yet another aspect of the invention, storing one or more transient conditions includes storing one or more transient conditions associated with meter diagnostics. According to still another aspect of the invention, storing one or more transient conditions includes storing one or more transient conditions associated with electrical service conditions.

According to another embodiment of the invention, there is disclosed a meter apparatus. The meter apparatus includes means for detecting transient conditions, a memory having a plurality of records that stores detected transient conditions for a current time period in a first record in the memory, at an end of the current time period, means for initializing a second record in the memory for storing detected transient conditions for another time period subsequent to the current time period, where the second record overwrites an oldest record in the memory, and means for presenting one or more of the stored transient conditions.

According to an aspect of the invention, the memory further includes instructions executable by a processor for identifying within records stored transient conditions in a billing period. According to another aspect of the invention, the means for presenting include a display for rending an indication of the stored transient conditions. According to yet another aspect of the invention, the means for presenting may include a communications module operable for transmitting an indication of the stored transient conditions. The communications module may be operating for transmitting to an automatic meter reading system. According to another aspect of the invention, the means for detecting includes at least one sensor. According to yet another aspect of the invention, the plurality of records corresponds to a number of days in a billing period.

According to another embodiment of the invention, there is disclosed a system for distributing electricity. The system includes a plurality of customer lines for receiving electricity from a utility company, at least one electricity meter coupled to each customer line, where each electricity meter includes a processor coupled to one or more sensors for detecting transient conditions, a queue for storing at least a portion of the detected transient conditions, and a communications system that provides communications between the electricity meters and the utility company.

According to an aspect of the invention, the queue may be a circular queue with a plurality of records for storing one or more detected transient conditions. According to another aspect of the invention, the communications system may be operable to communicate an indication of at least a portion of the detected transient conditions to the utility company. According to another aspect of the invention, the communications system includes an automatic meter reading system having at least one mobile vehicle for receiving the indication of at least a portion of the detected transient conditions. According to yet another aspect of the invention, the communications system includes a display for rendering an indication of at least a portion of the detected transient conditions.

### BRIEF DESCRIPTION OF THE DRAWINGS

Having thus described aspects of the invention in general terms, reference will now be made to the accompanying drawings, which are not necessarily drawn to scale, and wherein:

FIG. 1 illustrates an exemplary system overview diagram according to an embodiment of the present invention.

FIG. 2 illustrates an exemplary block diagram of an electricity meter according to an embodiment of the present invention.

FIG. 3 illustrates an exemplary circular queue according to an embodiment of the present invention.

FIG. 4 is an illustrative flowchart of daily processing in an exemplary meter according to an embodiment of the present invention.

### DETAILED DESCRIPTION OF THE INVENTION

The present invention is described below with reference to figures and flowchart illustrations of systems, methods, apparatuses and computer program products according to an embodiment of the invention. It will be understood that each block of the flowchart illustrations, and combinations of blocks in the flowchart illustrations, respectively, may be implemented by computer program instructions. These computer program instructions may be loaded onto a general purpose computer, special purpose computer, or other programmable data processing apparatus to produce a machine, such that the instructions which execute on the computer or other programmable data processing apparatus create means for implementing the functions specified in the flowchart block or blocks.

These computer program instructions may also be stored in a computer-readable memory that can direct a computer or other programmable data processing apparatus to function in a particular manner, such that the instructions stored in the computer-readable memory produce an article of manufacture including instruction means that implement the function specified in the flowchart block or blocks. The computer program instructions may also be loaded onto a computer or other programmable data processing apparatus to cause a series of operational steps to be performed on the computer or other programmable apparatus to produce a computer implemented process such that the instructions that execute on the computer or other programmable apparatus provide steps for implementing the functions specified in the flowchart block or blocks.

Accordingly, blocks of the flowchart illustrations support combinations of means for performing the specified functions, combinations of steps for performing the specified functions and program instruction means for performing the specified functions. It will also be understood that each block of the flowchart illustrations, and combinations of blocks in the flowchart illustrations, can be implemented by special purpose hardware-based computer systems that perform the specified functions or steps, or combinations of special purpose hardware and computer instructions.

Application programs that are components of the invention may include routines, programs, components, data structures, etc. that implements certain abstract data types, perform certain tasks, actions, or tasks. In a distributed computing environment, the application program (in whole or in part) may be located in local memory, or in other storage. In addition, or in the alternative, the application program (in whole or in part) may be located in remote memory or in storage to allow for the practice of the inventions where tasks are performed by remote processing devices linked through a communications network.

The present invention will now be described more fully hereinafter with reference to the accompanying figures, in which like numerals indicate like elements throughout the several drawings. Some, but not all embodiments of the invention are described. Indeed, these inventions may be embodied in many different forms and should not be construed as limited to the embodiments set forth herein; rather, these embodiments are provided so that this disclosure will satisfy applicable legal requirements, be thorough and complete, and will fully convey the scope of the invention to those skilled in the art.

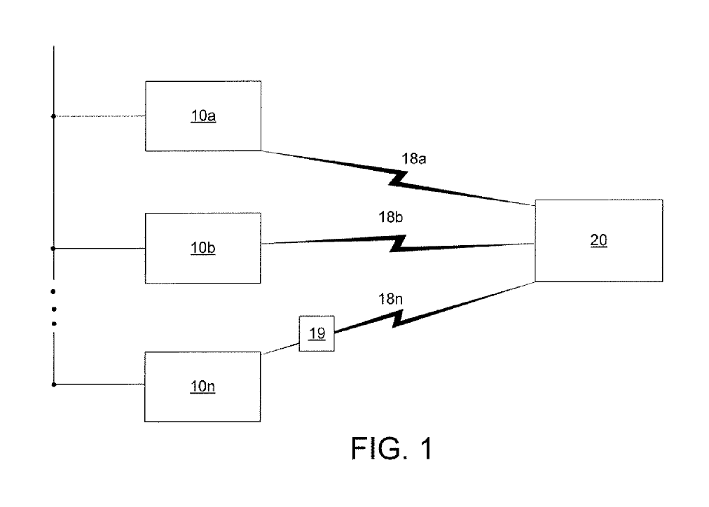

FIG. 1 illustrates an exemplary system overview diagram according to an embodiment of the present invention. Referring to FIG. 1, an electricity meter 10a . . . 10n, may be provided to each of a plurality of customer lines from which electricity may be received from a utility company 20. The meters 10a . . . 10n may monitor and store electricity usage and/or demand information for the plurality of customer lines. The meters may further monitor and record status information for the plurality of customer lines. The utility company 20 may interact with the meters 10a . . . 10n through respective signal paths 18a . . . 18n of a communications system to retrieve information from the meters. A variety of methods, both wired and wireless, may be utilized for the signal paths 18a . . . 18n of the communications system according to an embodiment of the present invention. For example, the electricity meters 10a . . . 10n may communicate through a telephone line, an automatic meter reading system 19, an optical port, an RS-232 line, wireless systems, and many other means of communications. In addition, receiving devices, such as hand-held devices may communicate with the electricity meters 10a . . . 10n. The receiving devices may then subsequently communicate any collected information to the utility company 20. The receiving devices may include cellular devices such as phones, PDAs, notebook computers, specialized receivers, or handheld devices. The receiving devices or aspects thereof may also be incorporated with mobile vehicles, including those utilized with automatic meter reading systems 19. The mobile vehicles may include vans, cars, ATVs, motorcycles, segways, planes, remote control planes, and a variety of other transportation vehicles. According to an embodiment, a drive-by vehicle such as a van may be utilized with an automatic meter reading system 19. According to another embodiment, a receiving device may be utilized by personnel visiting one or more electricity meters 10a . . . 10n. According to another embodiment, the utility company 20 may communicate with the electricity meters 10a . . . 10n remotely through a telephone line. Many other variations are well-known to one of ordinary skill in the art. Many variations will be recognized by one of ordinary skill in the art.

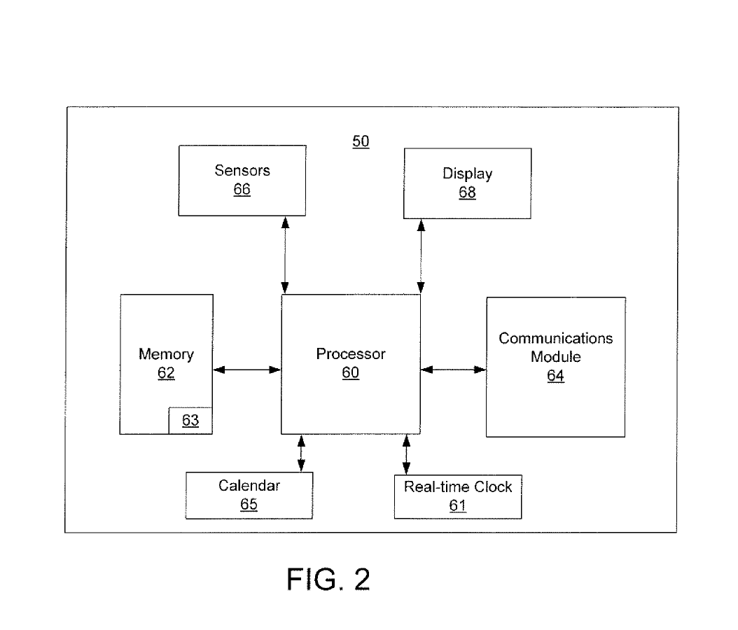

FIG. 2 illustrates an exemplary electricity meter 50 according to an embodiment of the present invention. The meter 50 may be coupled to an alternating current (AC) power source provided by the utility company. The meter 50 includes a processor 60, a memory 62, a communications module 64, one or more sensors 66, and a display 68. According to one embodiment, processor 60 may be a microprocessor with read-only memory (ROM) and/or random access memory (RAM). For example, processor 60 may be a 32 bit microcomputer with 2 Mbit ROM, 64 Kbit RAM. The processor 60 may also be in communications with a real-time clock 61 and a calendar 65, both of which may be discrete components or implemented in software stored in the memory 62. The memory 62 may include a variety of storage methods, including flash memory, electronically erasable programmable memory, read only memory (ROM), removable media, and other volatile and non-volatile storage devices as are understood by one of ordinary skill in the art. One of ordinary skill in the art will appreciate that the memory 62 may include a plurality of memories and memory modules.

Still referring to FIG. 2, the processor 60 may execute instructions 63 (e.g., software instructions) stored in the memory 62 and may also store data in the memory 62. The communications module 64 may be utilized for transmitting information to and perhaps for receiving information from the utility company. For example, the communications module 64 may include one or more of optical ports for communicating with an external reader, a telephone modem, an RS-232 line, a simple input/output (I/O) board, a complex I/O board, and a plurality of wireless and cellular technologies as understood by one of ordinary skill in the art. In addition, the communications module 64 may communicate with an automatic meter reading system, which may include a drive-by vehicle for communicating with the meter 50. The sensors 66 may include current and voltage sensors and may generate measurements of current and voltage. The sensors may also be able to detect transient conditions or indications of transient conditions. Further the sensors 66 may include or be in communication with analog-to-digital converters and/or digital signal processors. The display 68 may be utilized to display a plurality of information associated with the meter, including electricity usage and demand along with status alerts. The display 68 may be of virtually any display technology, including LCD, plasma, CRT, and analog-type displays. In addition, although not shown, the meter 50 may include a power source such as a battery. Implementations of meters 50 in accordance with embodiments of the present invention may be include other components as desired for the operation of a meter, such as are generally described in U.S. Pat. No. 6,778,920.

Electricity meters 50 in accordance with embodiments of the present invention may record a variety of transient conditions, which may occur for a period of time, but may go away on their own. Some of these transient conditions may be associated with the health of the meter hardware, peripherals and circuitry. Other transient conditions may also be associated with detecting signs of meter tampering, electricity theft, or equipment failure. Still other transient conditions may associated with monitoring the power quality.

In accordance with embodiments of the present invention, one or more of the following errors, cautions, and diagnostics may be detected as transient conditions by the meters 50. With respect to transient conditions such as errors, an error may indicate a problem with the hardware of meter 50. In such a situation, the meter 50 may have performed a self-check on its hardware, for instance by executing a set of software instructions, and may have found a problem with its hardware. For example, the error may be associated with a meter's RAM (random access memory), ROM (read-only memory), NVRAM (non-volatile random access memory)/EEPROM (electrically erasable programmable read-only memory), battery, or metering circuit. With respect to the metering circuit, the errs may be associated with the meter's analog to digital (A/D) converter or digital signal processor (DSP).

With respect to cautions, these transient conditions may include a low battery caution or a meter unprogrammed caution. With respect to electrical condition cautions, these transient conditions may include a demand threshold caution, where a programmed limit has been exceeded, and cautions related to leading kVarh and received kWh.

With respect to diagnostics, the transient conditions may include conditions related to Polarity/Cross Phase/Energy Flow, voltage imbalance, inactive phase current, phase angle imbalance, distortion alert, over voltage, or high neutral current.

Other errors, cautions, and diagnostics will be readily recognized by one of ordinary skill in the art. The utility companies may select the particular errors, cautions, diagnostics, or other transient conditions to be monitored by the electricity meters 50. If any of the conditions occurs, they may be detected and recorded by the electricity meters 50 as a transient condition.

Embodiments of the present invention may include electricity meters 50 with real-time clocks 61, calendars 65, and queues in memory 62 for recording transient conditions for enough calendar days to cover the maximum number of business days in a billing period. One of ordinary skill in the art will recognize that the time periods (e.g., day) may be varied according in accordance with embodiments of the invention. A billing period may cover the time between two consecutive meter readings, sometimes around 30 or 31 calendar days. The number of calendar days within a billing period may vary according to several factors, including holiday schedules and the ability of utility companies to dispatch meter readers on a timely basis. Because the maximum number of business days in a billing period excludes weekends and holidays, the total number of calendar days needed that may be supported by the queue may exceed the maximum number of business days in the billing period. These holidays may be programmed by the utility company in the calendar 65.

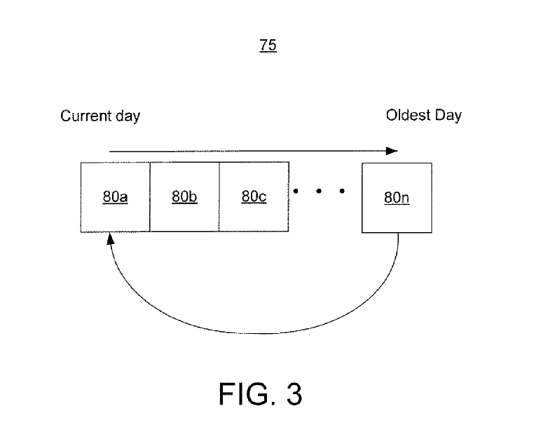

According to one embodiment of the present invention, the electricity meter 50 contains a queue for storing occurrences of transient conditions. Referring to FIG. 3, the queue 75, which is a circular queue in the illustrative embodiment, may include a plurality of locations or entries 80a-n (e.g., records) within the memory 62 located within the electricity meter 50. However, it will be understood that the queue 75 may generally include any array or plurality of memory locations or memory modules for storing information. One or more memory locations or entries 80a-n may be provided for a particular day such that there are sufficient numbers of memory locations or entries 80a-n to support a plurality of days. According to an aspect of the invention, the queue 75 may operate sequentially, such that a memory location or entry 80a-n corresponding to a previous or oldest entry may be overwritten by data for a current daily entry. For example, memory location or entry 80a may be associated with a current day while memory location 80n may be associated with an oldest previous day. Accordingly, the memory location or entry 80a-n for a current day shifts in a cycle as data is stored from one day to the next based on the number of days supported by the queue 75 (e.g., the number of locations or entries 80a-n). In other words, at some point in the cycle, a memory location or entry 80a-n associated with a previous time period (e.g., day) will be overwritten by an entry for a current time period (e.g., day).

According to an aspect of the invention, the circular queue 75 contains entries 80a-80n for enough calendar days to cover the maximum number of business days in a billing period for a utility company. This may ensure that transient conditions that occur during the billing period will be captured in the circular queue 75. Thus, transient conditions that occurred at any time during the billing period may be captured. In accordance with an embodiment of the present invention, it may not be required that the meter 50 be read only during the time window when the condition is present. In addition, the meter 50 can be read at any time of the month. The total number of calendar days that may be supported by the queue 75 will next be described.

According to one embodiment of the invention, the queue 75 covers 24 business days and records daily transient conditions for 38 calendar days. According to another embodiment of the invention, the queue 75 covers 21 business days and records daily transient conditions for 34 calendar days. According to yet another embodiment, the queue 75 records daily transient conditions for 35 calendar days. The queue 75 is circular in that transient conditions for a current time period (e.g., day) may be recorded over older transient conditions for a previous time period (e.g., day). Thus, transient conditions are cleared when they fall of the end of the queue 75 (e.g., are overwritten). One of ordinary skill in the art will recognize that other queues 75 may cover more or less business days than 21 or 24 business days and the number of calendar days recorded by the queue 75 would be adjusted accordingly.

According to an aspect of the present invention, each of these daily entries of the queue 75 is capable of recording one or more types of transient conditions, depending on the preferences of the utility company. The preferences of the utility company may be specified in the firmware (e.g., in memory 62) of the electricity meter 50. In an illustrative embodiment, a count of the occurrences of each transient condition are recorded each time period (e.g., day). Each time the transient condition occurs during the time period (e.g., day), the count may be incremented. A different count may be utilized for each transient conditioned that is to be monitored by one or more sensors 66. The total counts for each transient condition recorded during a time period (e.g., day) are stored in one of the entries of the queue 75. For example, if two electrical service conditions (e.g., demand overloads) were detected during the day, then the corresponding entry in the queue 75 may record the two occurrences. According to another embodiment of the present invention, a utility company may prefer to group several transient conditions together for a single counter. In such a case, the single counter may be incremented by an occurrence of any one of the several transient conditions. According to an embodiment of the present invention, information associated with one or more transient conditions may be presented on display 68.

According to an embodiment of the present invention, the meters 50 may be utilized with an automated meter reading (AMR) system 19. In particular, one-way or two-way AMR systems 19 may be utilized, wherein a mobile vehicle such as a drive-by-vehicle may receive information transmitted wirelessly from the meters 50. With the use of such AMR systems 19, the utility company does not need to dispatch a meter reader to visit (e.g., press a demand reset button or probe locally to clear the condition) or communicate with the meter 50 (e.g., remotely through a 2-way communication system) to acknowledge and clear the condition. Instead, as indicated above, transient conditions are maintained long enough to be read and are automatically cleared when they fall of the end of the queue 75.

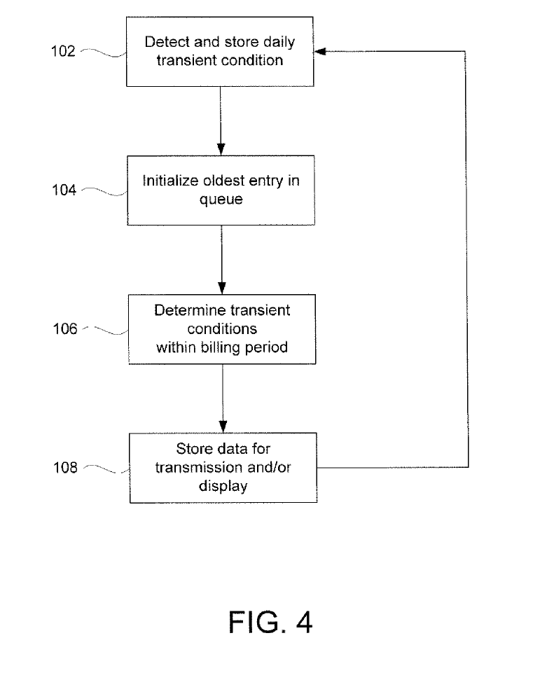

Referring to FIG. 4, in accordance with an illustrative embodiment of the present invention, at the end of each predetermined time period, such as a day, a meter 50 detects and stores the transient conditions that occurred during the day in one entry of the queue 75 already designated for that day (block 102). The detection of the transient conditions may be performed by the sensors 66 and/or software stored in memory 62. The meter 50 then initializes the oldest entry in the queue 75 for use for the current day as illustrated (block 104). The meter 50 searches the daily transient conditions circular queue 75 (block 106) and reports any transient conditions that occurred during that time period as illustrated (block 108). The process repeats for each day according to an illustrative embodiment. According to one embodiment, the meter 50 may have a real-time clock 61 to determine the end of each day. In such a case, the meter may determine that the end of a day is at midnight. According to another embodiment, the meter may determine that the end of the day occurs after 24 elapsed hours. One of ordinary skill in the art will recognize that other variations are possible.

One of ordinary skill in the art will recognize that while the above-described approaches were discussed with regard to electricity meters 50, aspect of the invention are equally applicable to other types of meters as well. For example, aspects of the invention may be applied to gas and/or water meters as well.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. A method for recording transient conditions in a meter, comprising:
providing a queue having a plurality of entries;
storing one or more transient conditions for a current time period in a first entry in the queue;
at an end of the current time period, initializing a second entry in the queue for storing transient conditions for another time period subsequent to the current time period, wherein the second entry overwrites an oldest entry in the queue; and
presenting one or more of the identified stored transient conditions.

2. The method of claim 1, wherein presenting the identified stored transient conditions comprises displaying the identified stored transient conditions on a display associated with the meter.

3. The method of claim 1, wherein presenting the identified stored transient conditions comprises transmitting the identified stored transient conditions to an automatic meter reading system.

4. The method of claim 1, wherein providing a queue comprises providing a queue having a plurality of entries based at least in part on a number of business days in a billing period.

5. The method of claim 1, wherein storing one or more transient conditions comprises storing one or more transient conditions associated with power quality.

6. The method of claim 1, wherein storing one or more transient conditions comprises storing one or more transient conditions associated with meter hardware errors.

7. The method of claim 1, wherein storing one or more transient conditions comprises storing one or more transient conditions associated with meter diagnostics.

8. The method of claim 1, wherein storing one or more transient conditions comprises storing one or more transient conditions associated with electrical service conditions.

9. A meter apparatus, comprising:
means for detecting transient conditions;
a memory having a plurality of records that stores detected transient conditions for a current time period in a first record in the memory;
at an end of the current time period, means for initializing a second record in the memory for storing detected transient conditions for another time period subsequent to the current time period, wherein the second record overwrites an oldest record in the memory; and
means for presenting one or more of the stored transient conditions.

10. The meter apparatus of claim 9, wherein the memory further comprises instructions executable by a processor for identifying within records stored transient conditions in a billing period.

11. The meter apparatus of claim 9, wherein the means for presenting comprise a display for rending an indication of the stored transient conditions.

12. The meter apparatus of claim 9, wherein the means for presenting comprise a communications module operable for transmitting an indication of the stored transient conditions.

13. The meter apparatus of claim 12, wherein the communications module is operable for transmitting to an automatic meter reading system.

14. The meter apparatus of claim 9, wherein the means for detecting comprises at least one sensor.

15. The meter apparatus of claim 9, wherein the plurality of records corresponds to a number of days in a billing period.

16. A system for distributing electricity, comprising:
a plurality of customer lines for receiving electricity from a utility company;
at least one electricity meter coupled to each customer line, wherein each electricity meter comprises:
a processor coupled to one or more sensors for detecting transient conditions;
a queue for storing at least a portion of the detected transient conditions; and
a communications system that provides communications between the electricity meters and the utility company.

17. The system of claim 16, wherein the queue comprises a circular queue with a plurality of records for storing one or more detected transient conditions.

18. The system of claim 16, wherein the communications system is operable to communicate an indication of at least a portion of the detected transient conditions to the utility company.

19. The system of claim 18, wherein the communications system comprises an automatic meter reading system having at least one mobile vehicle for receiving the indication of at least a portion of the detected transient conditions.

20. The system of claim 16, wherein the communications system comprises a display for rendering an indication of at least a portion of the detected transient conditions.
